(19) United States
(12) Patent Application Publication
(10) Pub. No.: US 2025/0341794 A1
(43) Pub. Date: Nov. 6, 2025

(54) EXPOSURE DEVICE AND IMAGE FORMING APPARATUS

(71) Applicant: CANON KABUSHIKI KAISHA, Tokyo (JP)

(72) Inventors: KOJI SUZUKI, Chiba (JP); HIROKI TAKANO, Saitama (JP); YUUTA SAKURAI, Chiba (JP); YU OGURO, Ibaraki (JP); AKIHISA YAMADA, Ibaraki (JP); KENJI SUZUKI, Chiba (JP); HIROSHI NAKAHATA, Chiba (JP); TAKEHIRO ISHIDATE, Tokyo (JP)

(21) Appl. No.: 19/193,416

(22) Filed: Apr. 29, 2025

(30) Foreign Application Priority Data
May 2, 2024 (JP) 2024-074766

(51) Int. Cl. G03G 15/04; B41J 2/45; G02B 19/00; G03G 15/00; H10K 59/82

(52) U.S. Cl. CPC G03G 15/04054; B41J 2/451; G03G 15/0409; G03G 15/80; H10K 59/82; G02B 19/0009; G02B 19/0047

(57) ABSTRACT

Provided is an exposure device having an extended shape in an axial direction to expose a photoreceptor, the exposure device including a substrate including a plurality of light emitting elements that emit light for exposing the photoreceptor arranged along the axial direction; a lens array for condensing light emitted from a light emitting element on the photoreceptor; a holder for holding the substrate and the lens array; a first contact electrically connected to the light emitting element for input of a signal for controlling emission of light; and a second contact positioned away from the first contact in a longitudinal direction of the substrate, the second contacted electrically connected to the light emitting element and for input of a signal for controlling emission of light emitting element.

### BACKGROUND

### Field

The present disclosure relates to an exposure device for exposing a photoreceptor and an image forming apparatus including the exposure device.

### Description of the Related Art

Conventionally, as an image forming apparatus of an electrophotographic system, an image forming apparatus including an exposure device that includes a light emitting diode (LED) array and a lens array, and forms an electrostatic latent image on a surface of a photoreceptor and develops a toner image by attaching a toner to the electrostatic latent image has been widely used. See, Japanese Patent Application Laid-Open No. 2020-62853.

In the conventional exposure device, a substrate on which an LED array is mounted is adhered to a holder by an adhesive, and a gap with the holder is sealed by a sealant. In addition, electrical connection between the substrate on which the LED array is mounted and a main body controller of the image forming apparatus is performed using a flexible flat cable (FFC). A connector is mounted on the substrate on which the LED array is mounted, and the FFC is detachably connected to the connector mounted on the substrate, whereby the connector is electrically connected to the main body controller of the image forming apparatus.

Further, in the conventional exposure device, as an assembly process of the exposure device, a position, a light quantity, and the like of the substrate are adjusted using a tool before adhering with the adhesive or after sealing with the sealant. At that time, similarly to the image forming apparatus, the substrate and the tool are electrically connected using the FFC to adjust the position, the light quantity, and the like of the substrate.

However, at the time of adjustment in the assembly process of the exposure device, there is a possibility that deflection occurs in a portion of the substrate where the LED array is mounted due to a force applied to the substrate by inserting and removing the FFC.

### SUMMARY

The present disclosure provided an exposure device having an extended shape in an axial direction to expose a photoreceptor, with the exposure device including a substrate including a plurality of light emitting elements configured to emit light for exposing the photoreceptor, the plurality of light emitting elements being arranged along the axial direction; a lens array configured to condense light emitted from at least one light emitting element of the plurality of light emitting elements; a holder configured to hold the substrate and the lens array; a first contact electrically connected to the at least one light emitting element and configured to input a signal for controlling emission of light, with the first contact being contactable to and separable from the at least one light emitting element' and a second contact positioned away from the first contact in a longitudinal direction of the substrate, the second contact being electrically connected to the at least one light emitting element, and configured to input a signal for controlling emission of light, with the contact being contactable to and separable from the at least one light emitting element.

Further features of the present disclosure will become apparent from the following description of exemplary embodiments with reference to the attached drawings.

### BRIEF DESCRIPTION OF THE DRAWINGS

FIGS. 1A, 1B, 1C, and 1D are diagrams for describing a substrate according to an embodiment;

FIG. 2 is a schematic cross-sectional view of an image forming apparatus;

FIG. 3 is a perspective view of an optical print head included in the image forming apparatus as viewed from above;

FIGS. 4A, 4B, and 4C are diagrams illustrating a substrate, and FIGS. 4D and 4E are diagrams illustrating a lens array;

FIG. 5 is an enlarged view of portions of a connector and a check pad of the substrate according to the embodiment;

FIG. 6 is a cross-sectional view illustrating a configuration of an optical print head;

FIG. 7 is a view of the optical print head as viewed from below;

FIG. 8 is an enlarged perspective view of the connector side of the optical print head; and

FIGS. 9A and 9B are diagrams illustrating a relationship between a check pad and a sealant according to the embodiment.

### DESCRIPTION OF THE EMBODIMENTS

Hereinafter, embodiments of the present disclosure will be exemplarily described in detail with reference to the drawings. However, dimensions, materials, shapes, relative arrangements, and the like of components described in the following embodiments should be appropriately changed depending on a configuration of an apparatus to which the present disclosure is applied and various conditions, and the scope of the present disclosure is not intended to be limited to them.

### Image Forming Apparatus

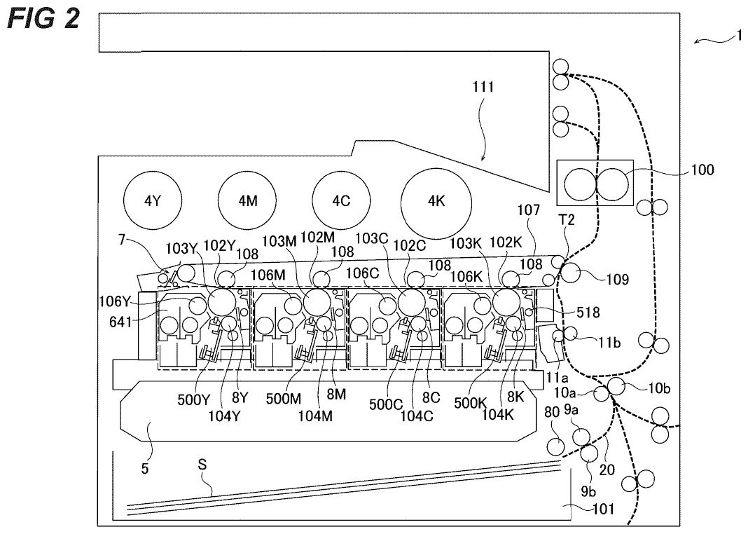

A schematic configuration of an image forming apparatus 1 will be described with reference to FIG. 2, which is a schematic cross-sectional view of the image forming apparatus 1. Although the image forming apparatus 1 illustrated in FIG. 2 is a color printer (multi function printer (MFP)) including a reading device, the embodiment may be a copying machine not including a reading device. Further, the embodiment is not limited to a so-called tandem type color image forming apparatus including a plurality of photosensitive drums 103 as illustrated in FIG. 2, and may be a color image forming apparatus including one photosensitive drum 103 or an image forming apparatus that forms a monochrome image.

The image forming apparatus 1 illustrated in FIG. 2 includes four image forming portions 102Y, 102M, 102C, and 102K (hereinafter, also collectively and simply referred to as the image forming portion 102) that form toner images of respective colors of yellow, magenta, cyan, and black.

The image forming portions 102Y, 102M, 102C, and 102K include photosensitive drums 103Y, 103M, 103C, and 103K (hereinafter, also collectively and simply referred to as the photosensitive drum 103), respectively. These photosensitive drums are arranged to be separated from each other.

Further, the image forming portions 102Y, 102M, 102C, and 102K include charging devices 104Y, 104M, 104C, and 104K (hereinafter, also collectively and simply referred to as the charging device 104) that charge the photosensitive drums 103Y, 103M, 103C, and 103K, respectively.

Further, the image forming portions 102Y, 102M, 102C, and 102K include exposure units 500Y, 500M, 500C, and 500K (hereinafter, also collectively and simply referred to as the exposure unit 500) that expose the photosensitive drums 103Y, 103M, 103C, and 103K, respectively. The image forming apparatus 1 illustrated in FIG. 2 is an image forming apparatus of a bottom surface exposure system that exposes the photosensitive drum 103 from below.

Further, the image forming portions 102Y, 102M, 102C, and 102K include development devices 106Y, 106M, 106C, and 106K (hereinafter, also collectively and simply referred to as the development device 106) that develop an electrostatic latent image on the photosensitive drum 103 with a toner and develop a toner image of each color on the photosensitive drum 103. Note that reference characters Y, M, C, and K indicate toner colors (yellow, magenta, cyan, and black).

The image forming apparatus 1 includes an intermediate transfer belt 107 to which toner images formed on the photosensitive drum 103 are transferred, and primary transfer rollers 108 (Y, M, C, and K) that sequentially transfer the toner images formed on the photosensitive drum 103 to the intermediate transfer belt. Further, the image forming apparatus 1 includes a secondary transfer roller 109 that transfers the toner image on the intermediate transfer belt 107 to a recording material S conveyed from a sheet feeding portion 101, and a fixing device 100 that fixes the secondarily transferred image to the recording material S.

Toners remain on the surfaces of the photosensitive drums 103Y, 103M, 103C, and 103K after the primary transfer. These residual toners are removed by drum cleaning devices (first cleaning devices) 8Y, 8M, 8C, and 8K (hereinafter, also collectively and simply referred to as the drum cleaning device 8), and recovered in a recovery toner container 5.

Also, the toner remains on the surface of the intermediate transfer belt 107 after the secondary transfer. The residual toner is removed by a belt cleaning device (second cleaning device) 7 and recovered in the recovery toner container 5.

### Image Forming Process

Next, an image forming process of the image forming apparatus will be briefly described. The charging device 104Y charges the surface of the photosensitive drum 103Y. The exposure unit 500Y exposes the surface of the photosensitive drum 103Y charged by the charging device 104Y. As a result, an electrostatic latent image is formed on the photosensitive drum 103Y. Next, the development device 106Y develops the electrostatic latent image formed on the photosensitive drum 103Y with a yellow toner. A yellow toner image developed on the surface of the photosensitive drum 103Y is transferred onto the intermediate transfer belt 107 by the primary transfer roller 108Y. Magenta, cyan, and black toner images are also formed by a similar image forming process and transferred so as to be superimposed on the intermediate transfer belt 107.

The toner image of each color transferred onto the intermediate transfer belt 107 is conveyed to a secondary transfer portion T2 by the intermediate transfer belt 107. A transfer bias for transferring the toner image to the recording material S is applied to the secondary transfer roller 109 disposed in the secondary transfer portion T2. The toner image conveyed to the secondary transfer portion T2 is transferred to the recording material S conveyed from the sheet feeding portion (sheet feeding cassette) 101 by the transfer bias of the secondary transfer roller 109.

The recording material S is stored in a form of being stacked in the sheet feeding portion 101, and is fed to a conveying path 20 according to image forming timing. In a sheet feeding method, first, a leading edge of the recording material S is lifted up by friction of a sheet feeding roller 80, and only one sheet of the recording material S is conveyed to the conveying path 20 by a pair of sheet separation conveying rollers 9a and 9b for preventing double feeding of the recording material S. Thereafter, the recording material S pulled out by a pair of conveying rollers 10a and 10b is conveyed to a pair of registration rollers 11a and 11b through the conveying path 20 and temporarily stopped. In the pair of registration rollers 11a and 11b, skew feeding correction and timing correction are performed, and then the recording material is conveyed to the secondary transfer portion T2.

The recording material S to which the toner image has been transferred by the secondary transfer portion T2 is conveyed to the fixing device 100. The fixing device 100 fixes the toner image to the recording material S by heat and pressure. The recording material S on which the fixing processing has been performed by the fixing device 100 is discharged to a sheet discharging portion 111.

As illustrated in FIG. 2, the image forming apparatus 1 further includes toner containers 4Y, 4M, 4C, and 4K (hereinafter, also collectively and simply referred to as the toner container 4). By performing the image formation, a toner amount in the development device 106 decreases. At that time, the toner is supplied from the toner containers 4Y, 4M, 4C, and 4K provided corresponding to the image forming portions 102Y, 102M, 102C, and 102K to the development device 106 via pipes.

### Configuration of Optical Print Head

Next, an optical print head (an exposure head and an exposure device) 105 included in the exposure unit 500 will be described. Here, as an example of an exposure system adopted in an image forming apparatus of an electrophotographic system, there is a laser beam scanning exposure system in which an irradiation beam of a semiconductor laser is scanned with a rotating polygon mirror or the like, to expose the photosensitive drum through an f-θ lens or the like. The optical print head 105 described in the present embodiment is used for an LED exposure system that exposes the photosensitive drum 103 using light emitting elements such as LEDs arranged along a rotational axis direction of the photosensitive drum 103, and is not used for the laser beam scanning exposure system described above.

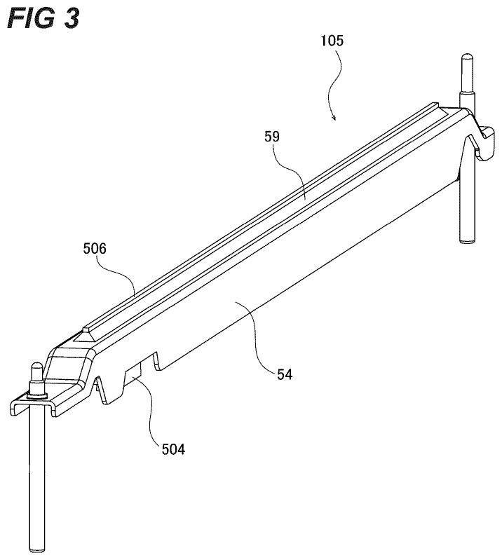

The optical print head 105 described in the present embodiment is provided below the rotational axis of the photosensitive drum 103 as a photoreceptor in a vertical direction, and LEDs 503 of the optical print head 105 expose the photosensitive drum 103 from below. FIG. 3 is a perspective view of the optical print head 105 included in the image forming apparatus 1 of the present embodiment as viewed from above.

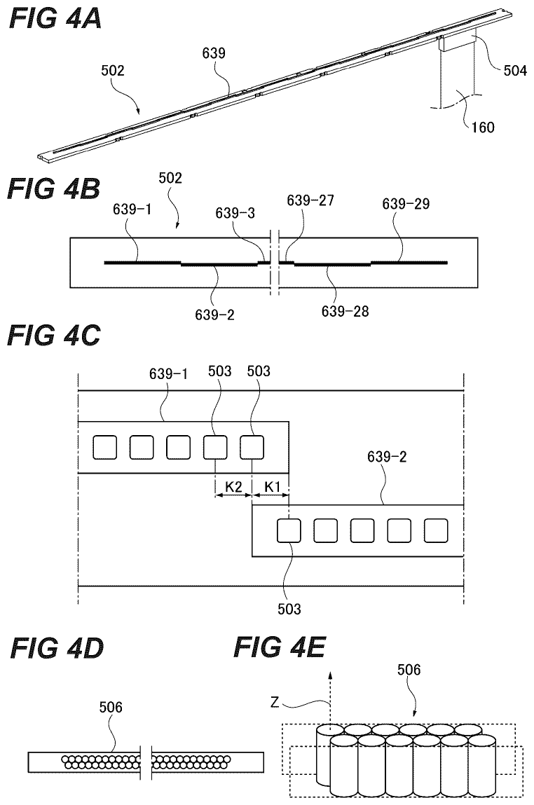

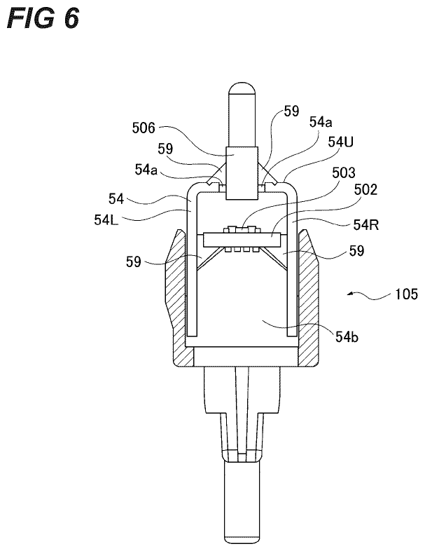

The optical print head (exposure head) 105 has a long shape (longitudinal shape) extending in the rotational axis direction of the photosensitive drum 103. The optical print head 105 includes a substrate 502, light emitting elements mounted on the substrate 502, a lens array 506, and a holder 54 that holds the substrate 502 and the lens array 506. Here, the optical print head 105 includes light emitting diodes 503 (hereinafter referred to as the LEDs) as the light emitting elements that emit light (see FIG. 4C). The substrate 502 is installed inside the holder 54. The holder 54 is provided with a lens attachment portion (first opening 54a in FIG. 6) for attaching the lens array 506.

The holder 54 is a metal thin plate having a thickness of about 1 mm, and is a component obtained by processing an electrogalvanized steel sheet with a press die.

The lens attachment portion (first opening 54a in FIG. 6) of the holder 54 is an opening slightly larger than the lens array 506, and the lens array 506 is fixed to the holder 54 with an adhesive. Further, the substrate 502 is formed to be slightly smaller than the holder 54, and a position of the substrate 502 is adjusted such that an optical axis of the LED 503 is aligned with the center of the lens array 506. Then, the substrate 502 is fixed to the holder 54 by an adhesive between the holder 54 and wall surfaces on both sides of the substrate 502 in a short direction, i.e., a direction orthogonal to a longitudinal direction of the holder 54. This adhesive is, for example, an ultraviolet curable adhesive, and is cured by being applied to an adhering point in a liquid or gel state and then irradiated with ultraviolet rays.

The substrate 502 held by the holder 54 will be described. FIG. 4A is a schematic perspective view of the substrate 502. FIG. 4B illustrates an arrangement of a plurality of LEDs 503 provided on the substrate 502 on the substrate 502. FIG. 4C is an enlarged view of FIG. 4B.

An LED chip 639 is mounted on the substrate 502. As illustrated in FIG. 4A, the LED chip 639 is provided on one surface of the substrate 502, and a long FFC connector 504 is provided on the other surface (surface opposite to the side on which the light emitting elements are arranged). The FFC connector 504 is attached to a bottom surface of the substrate 502 such that the longitudinal direction thereof extends along the longitudinal direction of the substrate 502. A wire for supplying a signal to each LED chip 639 is provided on the substrate 502. One end of a flexible flat cable (hereinafter, also referred to as an FFC) 160 as an example of a cable is detachably connected to the connector 504.

A main body of the image forming apparatus 1 is provided with a control board including a controller and a connector. The other end of the FFC 160 is connected to the connector included in the control board. That is, the FFC 160 electrically connects the control board (controller) of the main body of the image forming apparatus 1 and the substrate 502 of the optical print head 105. A control signal (drive signal) is input to the substrate 502 from the controller of the main body of the image forming apparatus 1 via the FFC 160 and the connector 504. The LED chip 639 is driven by the control signal input to the substrate 502.

The LED chip 639 mounted on the substrate 502 will be described. As illustrated in FIGS. 4B and 4C, a plurality of LED chips 639-1 to 639-29 (29 LED chips) in which a plurality of LEDs 503 (an example of a light emitting element) is arranged is arranged on one surface of the substrate 502. In each of the LED chips 639-1 to 639-29, a plurality of LEDs 503 are arranged in a row in the longitudinal direction thereof. In the longitudinal direction of the LED chip 639, a center-to-center distance k2 between the adjacent LEDs 503 corresponds to the resolution of the image forming apparatus 1.

The LED chips 639-1 to 639-29 are alternately arranged in two rows along the rotational axis direction of the photosensitive drum 103. That is, as illustrated in FIG. 4B, odd-numbered LED chips 639-1, 639-3, . . . , and 639-29 counted from the left side are mounted in a row in the longitudinal direction of the substrate 502, and even-numbered LED chips 639-2, 639-4, . . . , and 639-28 are mounted in a row in the longitudinal direction of the substrate 502. By arranging the LED chips 639 in this way, as illustrated in FIG. 4C, in the longitudinal direction of the LED chip 639, a center-to-center distance k1 between the LEDs arranged at one end of one LED chip 639 and the other end of the other LED chip 639 in the different adjacent LED chips 639 can be equalized to the center-to-center distance k2 between the adjacent LEDs 503 on one LED chip 639.

In the present embodiment, the light emitting element (light emitting portion) is a semiconductor LED which is a light emitting diode, but may be, for example, an organic light emitting diode (OLED). This OLED is also called organic electro-luminescence (EL), and is a current-driven light emitting element. The OLEDs are arranged on a line along a main scanning direction (axial direction of the photosensitive drum 2) on a thin film transistor (TFT) substrate, for example, and are electrically connected in parallel by a power supply wire similarly provided along the main scanning direction.

Next, the lens array 506 which is a lens assembly will be described. FIG. 4D is a schematic view of the lens array 506 as viewed from the photosensitive drum 103 side. FIG. 4E is a schematic perspective view of the lens array 506. As illustrated in FIG. 4D, the lens array 506 condenses the light emitted from the light emitting element on the photosensitive drum 103. The lens array 506 is a lens assembly including a plurality of lenses. The plurality of lenses is arranged in two rows along the longitudinal direction of the plurality of LEDs 503. Each lens is alternately arranged such that one of the lenses in the other column is arranged so as to be in contact with both of the adjacent lenses in the longitudinal direction of the lenses in one column. Each lens is a cylindrical rod lens made of glass or plastic. The shape of the lens is not limited to the cylindrical shape, and may be, for example, a polygonal prism such as a hexagonal prism.

A dotted line Z illustrated in FIG. 4E indicates an optical axis of the lens. The optical print head 105 is movable by a moving mechanism in a direction substantially along the optical axis of the lens (also referred to as the optical axis direction) indicated by the dotted line Z. The optical axis of the lens mentioned here means a line connecting the center of a light exit surface of the lens and a focal point of the lens. The lens array 506 is a lens assembly having a plurality of lenses, and the optical axis described above is an optical axis of an arbitrary lens among the plurality of lenses. Here, strictly speaking, the plurality of lenses included in the lens array 506 may be slightly inclined to each other. This is due to tolerance during assembly. However, deviations within the tolerance mentioned here are not considered for defining the direction of the optical axis. Therefore, it is considered that the optical axes of the plurality of lenses each extend in the same direction. The lens array 506 has a function of condensing the light emitted from the LED 503 on the surface of the photosensitive drum 103. That is, radiated light emitted from the LED 503 is incident on the lens included in the lens array 506. The lens has a function of condensing the incident radiated light on the surface of the photosensitive drum 103.

An attachment position of the lens array 506 with respect to the lens attachment portion (first opening 54a in FIG. 6) is adjusted at the time of assembling the optical print head 105. Specifically, the attachment position of the lens array 506 with respect to the lens attachment portion (first opening 54a in FIG. 6) is adjusted such that a distance between a light emitting surface of the LED 503 and a light entrance surface of the lens is substantially equal to a distance between the light exit surface of the lens and the surface of the photosensitive drum 103.

### (Configuration of Substrate)

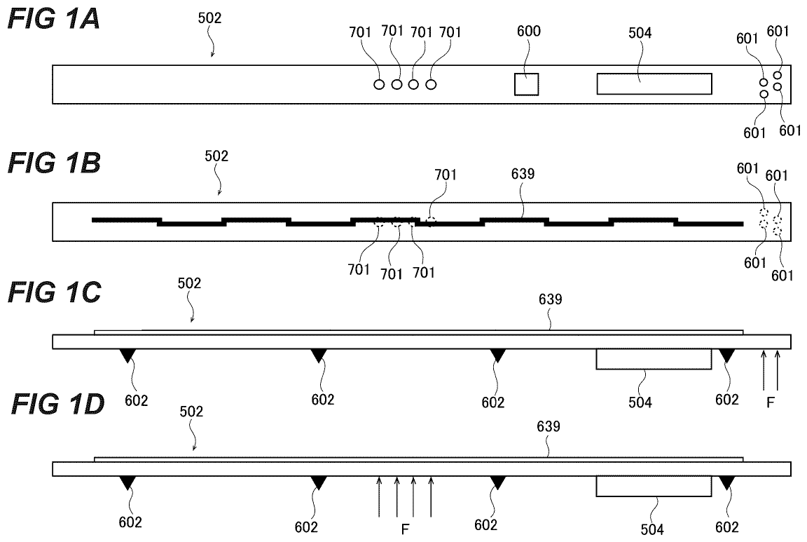

The configuration of the substrate 502 will be described in more detail with reference to FIGS. 1A, 1B, 1C, 3, and 5.

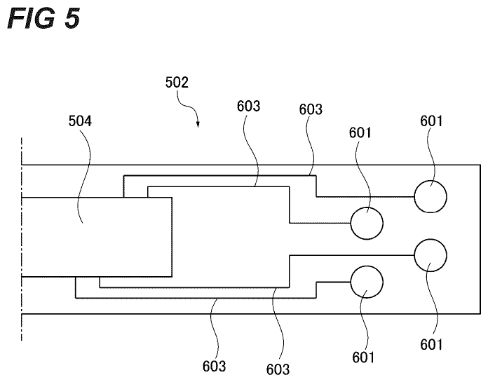

FIG. 1A is a diagram of the substrate 502 as viewed from the connector 504 side. FIG. 1B is a diagram of the substrate 502 as viewed from the LED chip 639 side. FIG. 1C is a diagram of the substrate 502 as viewed from a side profile. FIG. 5 is an enlarged view of portions of a connector 504 and a check pad 601 of the substrate 502.

As illustrated in FIGS. 1A to 1C, the substrate 502 has a longitudinal shape extending in the axial direction of the photosensitive drum 103.

As illustrated in FIGS. 1B and 1C, the substrate 502 includes the plurality of LED chips 639 in which the plurality of LEDs 503 is arranged, and the LED chips 639 are mounted on one surface of the substrate 502.

As illustrated in FIG. 1A, the substrate 502 includes an IC 600 that controls light emission of the LED chip 639. The IC 600 is mounted on a surface of the substrate 502 opposite to the surface on which the LED chip 639 is mounted. The IC 600 is electrically connected to the LED chip 639.

As described above, a wire for supplying a signal to the LED chip 639 is provided on the substrate 502. Among wires of the substrate 502, a plurality of wires for supplying a control signal for controlling light emission of each LED chip 639 is connected to the IC 600. The plurality of wires connected to the IC 600 is connected to each LED chip 639. As described above, the IC 600 is electrically connected to the LED chip 639 by the wire of the substrate 502.

As illustrated in FIGS. 1A and 1C, the substrate 502 includes the FFC connector 504 to which the FFC 160 is detachably connected. The FFC connector 504 is mounted on a surface of the substrate 502 opposite to the surface on which the LED chip 639 is mounted. The FFC connector 504 is electrically connected to the LED chip 639.

Among the wires of the substrate 502 described above, a wire for supplying a control signal for controlling light emission of the LED chip 639 is connected to the FFC connector 504. The wire that is connected to the FFC connector 504 and supplies a control signal is connected to the IC 600. That is, the FFC connector 504 is electrically connected to the LED chip 639 via the IC 600.

Among the wires of the substrate 502 described above, a wire for supplying power for controlling light emission of the LED chip 639 is connected to the FFC connector 504. The wire that is connected to the FFC connector 504 and supplies power is connected in parallel to each LED chip 639. The wire that is connected to the FFC connector 504 and supplies power is directly connected to the LED chip 639 without passing through the IC 600.

### Contact of Substrate

As illustrated in FIG. 1A, the substrate 502 further includes a first check pad 601 as a first contact and a second check pad 701 as a second contact, separately from the FFC connector 504. The second check pad 701 is provided at a position different from the first check pad 601 in the longitudinal direction of the substrate 502.

### First Check Pad

A plurality of first check pads 601 is provided. In other words, the first check pads 601 include a plurality of contacts. The first check pad 601 is provided on a surface of the substrate 502 opposite to the surface on which the LED chip 639 is mounted. The first check pad 601 is a copper foil portion provided on the substrate 502, and is a contact with which a contact probe as a contact terminal connected to an adjustment tool in a contactable and separable manner. A signal for controlling light emission of the LED chip 639 is input to the first check pad 601 through the contact probe as the contact terminal that comes in contact with the first check pad 601 in a contactable and separable manner.

The plurality of first check pads 601 is electrically connected to the LED chip 639. As illustrated in FIG. 5, each of the plurality of first check pads 601 is electrically connected to the FFC connector 504 by the wire 603 of the substrate 502. A plurality of wires 603 connecting the first check pads 601 and the FFC connector 504 includes wires for supplying a control signal for controlling light emission of the LED chip 639 and wires for supplying power for controlling light emission of the LED chip 639.

In other words, the plurality of first check pads 601 includes contacts connected to the wires that are connected to the FFC connector 504 and supply a control signal for controlling light emission of the LED chip 639. Further, the plurality of first check pads 601 includes contacts connected to the wires that are connected to the FFC connector 504 and supply power for controlling light emission of the LED chip 639.

As illustrated in FIG. 1A, the first check pad 601 is disposed at one end of the substrate 502 in the longitudinal direction.

The first check pad 601 is disposed closer to one end than the FFC connector 504 in the longitudinal direction of the substrate 502. In the present embodiment, as illustrated in FIG. 1A, the FFC connector 504 is disposed closer to one end than the center in the longitudinal direction of the substrate 502, and the first check pad 601 is disposed closer to the end than the FFC connector 504.

Note that since the substrate 502 illustrated in FIG. 1A has a configuration in which the FFC connector 504 is disposed closer to the end in the longitudinal direction of the substrate 502 than the IC 600, it can be said that the first check pad 601 is disposed closer to the end than the IC 600 in the longitudinal direction of the substrate 502.

As illustrated in FIG. 1B, the first check pad 601 is disposed at a position not overlapping a region of the substrate 502 where the LED chip 639 is mounted on the front and back surfaces of the substrate 502. In other words, the first check pad 601 is disposed at a position not overlapping the LED chip 639 in the longitudinal direction of the substrate 502. In addition, the first check pad 601 is disposed outside a region of the substrate 502 where the LED chip 639 is mounted in the longitudinal direction of the substrate 502.

At least some of the plurality of first check pads 601 are arranged side by side in the short direction orthogonal to the longitudinal direction of the substrate 502. Here, as illustrated in FIG. 1A, a configuration in which four first check pads 601 are arranged is illustrated. The four first check pads 601 are provided to be arranged in two rows (a plurality of rows) in the short direction.

### Second Check Pad

Similarly to the first check pads 601, a plurality of second check pads 701 is provided. In other words, the second check pads 701 include a plurality of contacts. The second check pad 701 is provided on the surface of the substrate 502 opposite to the surface on which the LED chip 639 is mounted. The second check pad 701 also has a function similar to that of the first check pad 601. That is, the second check pad 701 is a copper foil portion provided on the substrate 502, and is a contact with which a contact probe as a contact terminal connected to an adjustment tool in a contactable and separable manner. The second check pad 701 is a contact provided separately from the first check pad 601. In addition, a signal for controlling light emission of the LED chip 639 is input to the second check pad 701 through the contact probe as the contact terminal that comes in contact with the second check pad 701 in a contactable and separable manner.

The plurality of second check pads 701 is also electrically connected to the LED chip 639, similarly to the plurality of first check pads 601 described above. Since the electrical connection of the plurality of second check pads 701 is similar to the electrical connection of the plurality of first check pads 601 described above, the description thereof is incorporated by reference without being repeated here.

The second check pad 701 is disposed inside the first check pad 601 in the longitudinal direction of the substrate 502. Here, as illustrated in FIG. 1A, the second check pad 701 is disposed at the center of the substrate 502 in the longitudinal direction.

The plurality of second check pads 701 are arranged side by side in the longitudinal direction of the substrate 502. Here, as illustrated in FIG. 1A, a configuration in which four second check pads 701 are arranged is illustrated. The four second check pads 701 are provided to be arranged in a row in the longitudinal direction.

In addition, as described above, the FFC connector 504 is electrically connected to the IC 600 by the wire for supplying a control signal, and is electrically connected to the LED chip 639 by the wire for supplying power. Furthermore, the IC 600 is electrically connected to the LED chip 639 by the wire for supplying a control signal. In this manner, the first check pad 601 and the second check pad 701 are electrically connected to the LED chip via the FFC connector 504 by the wires of the substrate 502.

### Adjustment of Position and Light Quantity of Substrate

The substrate 502 is adhered and fixed to the holder 54 by the adhesive as described above at the time of assembling the optical print head 105. Before the substrate 502 is adhered and fixed to the holder 54, the substrate 502 and a tool are electrically connected to adjust the position, the light quantity, and the like of the substrate 502. The first check pad 601 provided on the substrate 502 is used to adjust the position, the light quantity, and the like of the substrate 502.

Among the plurality of contacts included in the substrate 502 according to the present embodiment, the first check pad 601 as the first contact is disposed at one end in the longitudinal direction of the substrate 502 as described above. In addition, the first check pad 601 is disposed at a position not overlapping the region of the substrate 502 where the LED chip 639 is mounted on the front and back surfaces of the substrate 502.

During the above-described adjustment at the time of assembling the optical print head 105, as illustrated in FIG. 1C, the substrate 502 is suction mounted at a plurality of positions in the longitudinal direction of the substrate 502 by suction pads 602. Then, warpage and deflection of the substrate 502 are corrected. A contact probe electrically connected to the tool is then brought into contact with the first check pad 601 provided on the substrate 502.

For example, as the contact probe, the same number of probes as the number of the first check pads 601 are fixed to a supporting member according to the positions of the first check pads 601. In each probe, a contact rod (plunger) in contact with the check pad is slidably supported by a hollow cylindrical member (barrel and pipe), and is biased in a moving direction by a biasing member (spring) provided in the cylindrical member. With this configuration, even if the substrate 502 is moved for position adjustment, the contact rod of the probe strokes following the movement of the substrate 502, so that the probe and the first check pad 601 are not separated from each other and the contact state is maintained.

In order to maintain this contact state, a pressing force F of the probe acts on the substrate 502. In the present embodiment, as illustrated in FIG. 1A, the first check pad 601 is disposed at one end of the substrate 502 in the longitudinal direction. Therefore, the pressing force F (FIG. 1C) of the probe is generated at the end in the longitudinal direction of the substrate 502 on which the first check pad 601 is disposed, so that a portion other than the end of the substrate 502 is hardly affected by the pressing force F of the probe. As a result, according to the present embodiment, it is possible to suppress the influence of the deflection of the portion of the substrate 502 on which the LED chip 639 is mounted due to the application of the pressing force F to the substrate 502.

Furthermore, in the present embodiment, the first check pad 601 is disposed outside the mounting region of the LED chip 639 on the substrate 502. Therefore, it is possible to minimize the influence of the deflection of the portion of the substrate 502 on which the LED chip 639 is mounted due to application of the pressing force F to the substrate 502.

At the time that the above-described adjustment is performed, the FFC 160 may be used instead of the first check pad 601. However, in a case where the FFC 160 is used at the time of adjustment, an operation of inserting the FFC 160 into the FFC connector 504 or pulling out the FFC 160 from the FFC connector 504 occurs. Since the substrate 502 on which the LED chip 639 is mounted is long, there is a possibility that deflection occurs in the portion of the substrate 502 on which the LED chip 639 is mounted due to the force applied to the substrate 502 when the FFC 160 is inserted and removed. In particular, when the FFC connector 504 overlaps the mounting region of the LED chip 639 on the front and back surfaces of the substrate 502, an excessive force is applied to the mounting region of the LED chip 639 of the substrate 502, and there is a possibility that a larger deflection occurs in the portion of the substrate 502 on which the LED array is mounted.

The substrate 502 according to the present embodiment is provided with the first check pad 601 separately from the FFC connector 504. Since the pressing force F of the contact probe acting on the substrate 502 is in a range in which the contact state is maintained at the time of adjusting the position of the substrate, the pressing force F is very small as compared with the force of inserting and removing the FFC 160 into and from the FFC connector 504 having the force of holding the FFC 160. That is, the pressing force F of the contact probe acting on the substrate 502 is very small as compared with the force applied to the substrate 502 when the FFC connector 504 is inserted and removed. Moreover, in the configuration in which the contact probe is separated from the first check pad 601 as in the present embodiment, no force is applied to the substrate 502 when the FFC 160 is pulled out. Therefore, it is possible to minimize the influence of the deflection of the portion of the substrate on which the LED chip is mounted due to application of an excessive force to the substrate.

As described above, the signal for controlling the light emission of the LED chip 639 is input to the substrate 502 through the electrical connection between the contact probe and the first check pad 601, and the position of the substrate 502 is adjusted in a state where the LED chip 639 of the substrate 502 is caused to emit light. Then, when the position is determined, the substrate 502 is adhered and fixed to the holder 54 with the adhesive.

### Sealing of Optical Print Head

At the time of assembling the optical print head, the substrate 502 adhered and fixed to the holder 54 further seals the gap with the holder 54 with a sealant.

As described above, similarly to the substrate 502, the lens array 506 is also adhered and fixed to the holder 54 with the adhesive. The gap between the lens array 506 and the holder 54 is also sealed with the sealant.

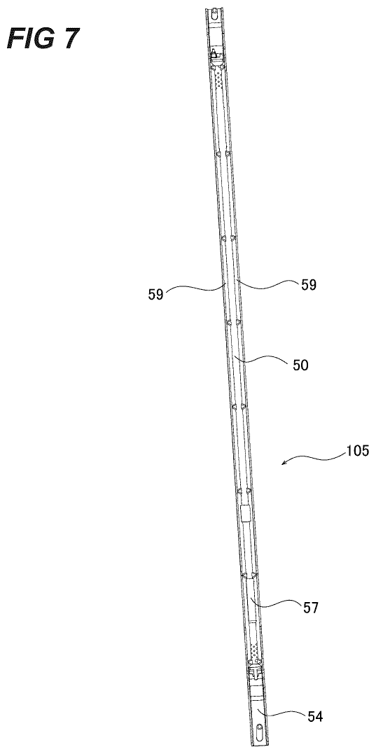

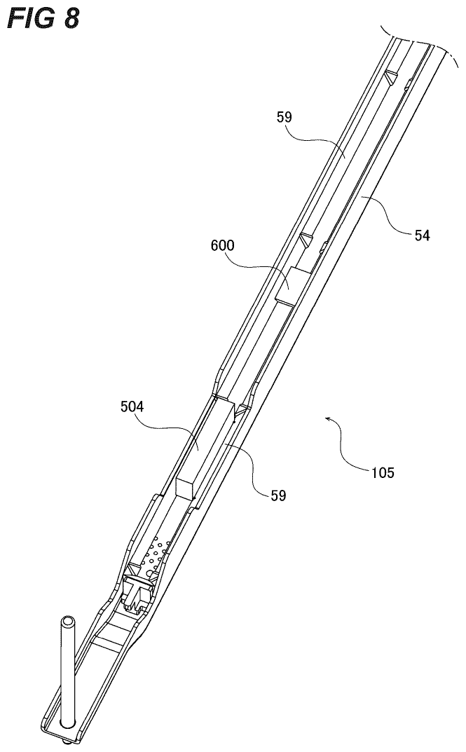

Sealing of the optical print head 105 with the sealant will be described with reference to FIGS. 3 and 6 to 8. FIG. 6 is a cross-sectional view illustrating a configuration of the optical print head 105. FIG. 7 is a view of the optical print head 105 in a state in which the substrate 502 is assembled to the holder 54 as viewed from below. FIG. 8 is an enlarged perspective view of a connector side (front side) of the optical print head 105 illustrated in FIG. 7.

As illustrated in FIG. 6, the holder 54 holds the lens array 506 and the substrate 502. In the present embodiment, the holder 54 is a metal member formed by bending a plate material obtained by plating a galvanized steel sheet or a cold-rolled steel sheet. For example, the holder 54 is formed by pressing a sheet metal such as an iron thin plate into a U shape. Hereinafter, the shape of the holder 54 will be described.

As illustrated in FIG. 6, the holder 54 has a planar portion (opposing surface) 54U in which the first opening 54a into which the lens array 506 is inserted is formed. The planar portion 54U faces the photosensitive drum 103 in the optical axis direction of the lens of the lens array 506. Note that the planar portion 54U is not limited to a plane, and may be a slightly curved surface. In addition, the holder 54 has an extending portion 54R extending in a direction separated from the photosensitive drum 103 from one side in the short direction of the planar portion 54U. In addition, the holder 54 has an extending portion 54L extending in a direction separated from the photosensitive drum 103 from the other side in the short direction of the planar portion 54U.

The extending portion 54R and the extending portion 54L form a substrate supporting portion for supporting the substrate 502 inserted from a second opening 54b in the holder 54. The planar portion 54U and the substrate supporting portion (extending portions 54R and 54L) are integrated to form the holder 54 that holds the lens array 506 and the substrate 502, and a cross section thereof is formed in a substantially U shape. Since the holder 54 is formed in a substantially U shape, the second opening 54b is formed on the side opposite to the planar portion 54U. The second opening 54b is formed between the substrate supporting portions (extending portions 54L and 54R) extending from the planar portion 54U to the side separated from the photosensitive drum.

The substrate 50 is inserted from the second opening 54b, that is, from the lower side of the U-shaped holder 54, and is adhered to the inside of each substrate supporting portion (the inside of the extending portion 54L and the inside of the extending portion 54R) with an adhesive. Since the position of the substrate 502 in a focusing direction is determined by a jig, the optical print head 105 does not include a positioning unit in the focusing direction of the substrate 50.

In addition, the lens array 506 is also adhered to the planar portion 54U with an adhesive in a state of being inserted into the first opening 54a formed in the planar portion 54U. The lens array 506 is fixed to the planar portion 54U (holder 54) after the position and inclination in the focusing direction are adjusted by the jig such that the distance in the focusing direction between all the LED chips 639 mounted on the substrate 50 and the lens array 506 becomes a predetermined value. The lens array 506 is fixed to the planar portion 54U at a plurality of positions in the longitudinal direction by an adhesive. That is, the optical print head 105 of the present embodiment has a plurality of adhering points for adhering and fixing the lens array 506 inserted into the first opening 54a to the planar portion 54U in the longitudinal direction of the planar portion 54U.

After the position adjustment and the fixing of the substrate 502 and the lens array 506 with respect to the holder 54, a gap between the substrate 502 inserted into the second opening 54b and the holder 54 (extending portions 54L and 54R) is sealed in the longitudinal direction by a sealant 59 as illustrated in FIGS. 7 and 8. Further, the gap between the substrate 502 and the holder 54 is also sealed in the short direction by the sealant, and the gap between the periphery of the substrate 502 and the holder 54 is sealed by the sealant. This prevents the LED 503 from being contaminated by toner and dust from the outside. Here, the sealant 59 seals the gap (boundary portion) between the substrate 502 and the holder 54, leaving most of the FFC connector 504 and the substrate 502 exposed.

Similarly, the sealant 59 is applied to a gap between the lens array 506 inserted into the first opening 54a and the holder 54 (planar portion 54U), and the gap is sealed by the sealant 59 in the longitudinal direction, as illustrated in FIG. 3. More specifically, as illustrated in FIG. 3, the sealant 59 seals a gap between the side wall of the lens array 506 and the edge of the first opening 54a along the longitudinal direction of the holder 54. As a result, it is possible to reduce the possibility that dust such as toner flows in from the gap between the side wall of the lens array 506 and the first opening 54a and the light emitted from the LED 503 is blocked by the dust. As a matter of course, the gap sealed by the sealant 59 seals not only the gap between the side wall on one side of the lens array 506 and the edge of the first opening 54a, but also the gap between the side wall on the other side of the lens array 506 and the edge of the first opening 54a. The side wall on the other side of the lens array 506 refers to a side wall opposite to the side wall on one side of the lens array 506. Also in this case, the gap (boundary portion) between the holder 54 and the lens array 506 is sealed with the sealant 59. This prevents the LED 503 from being contaminated by toner and dust from the outside.

### Inspection of Optical Print Head

As described above, the optical print head 105 that has been completely sealed with the sealant 59 is electrically connected to the substrate 502 and a tool to perform inspection such as an imaging state before being assembled to the image forming apparatus 1. This is an inspection process of inspecting the completed optical print head 105 for functional defects and the like at the time of adhering and sealing after position adjustment of the substrate 502 and the lens array 506 and in subsequent processes, and performing final light quantity adjustment. The second check pad 701 provided on the substrate 502 is used when the optical print head 105 is inspected before the assembly.

Among the plurality of contacts included in the substrate 502 according to the present embodiment, the second check pad 701 as the second contact is disposed inside the first check pad 601 in the longitudinal direction of the substrate 502 as described above. Here, the second check pad 701 is disposed at the center of the substrate 502.

On the other hand, the first check pad 601 is disposed at the end in the longitudinal direction of the substrate 502 as described above. As a result, the influence of the deflection when the pressing force of the contact probe is applied to the portion of the substrate 502 on which the LED chip 639 is mounted or the entire optical print head 105 can be minimized. However, a gap between the substrate 502 and the holder 54 around the substrate is sealed with the sealant 59. At the time of sealing with the sealant 59, there is a possibility that the sealant 59 is applied onto any of the plurality of first check pads 601. In particular, when the plurality of first check pads 601 is arranged side by side in the short direction of the substrate 502, a distance between the sealant 59 and the first check pad 601 cannot be secured, and there is a high possibility that the sealant is unintentionally applied onto the first check pad 601. For this reason, there is a possibility that the first check pad 601 cannot be used at the time of pre-shipment inspection for confirming an imaging state performed after sealing with the sealant 59.

Therefore, in the present embodiment, the second check pad 701 is provided on the substrate 502 separately from the first check pad 601. In addition, the second check pad 701 is provided inside the first check pad 601 in the longitudinal direction of the substrate 502. When the optical print head 105 is inspected, the second check pad 701 can be used even if the first check pad 601 cannot be used. As a result, it is possible to adjust the final light quantity or the like while minimizing the deflection of the substrate 502.

When the optical print head 105 is inspected before being assembled to the image forming apparatus, the substrate 502 is suction mounted at a plurality of positions in the longitudinal direction of the substrate 502 by the suction pads 602 as illustrated in FIG. 1D. Then, a contact probe electrically connected to the tool is brought into contact with the second check pad 701 provided on the substrate 502.

In order to maintain this contact state, a pressing force F of the probe acts on the substrate 502. In the present embodiment, as illustrated in FIG. 1A, the second check pad 701 is disposed at the center of the substrate 502 in the longitudinal direction. Therefore, the pressing force F (FIG. 1D) of the probe is generated at the center in the longitudinal direction of the substrate 502 on which the second check pad 701 is disposed.

However, when the optical print head 105 is inspected, unlike when the adjustment is performed, the substrate 502 is adhered and fixed to the holder 54, and is further sealed. Therefore, even if the second check pad 701 is disposed at a position overlapping the region of the substrate 502 where the LED chip 639 is mounted on the front and back surfaces of the substrate 502, the influence of the deflection applied to the entire optical print head 105 can be suppressed.

In addition, both the first check pad 601 and the second check pad 701 described above have a function of causing the LED chip 639 to emit light. That is, the check pads having the same function are provided at different positions on the substrate 502.

### Check Pad After Application of Sealant

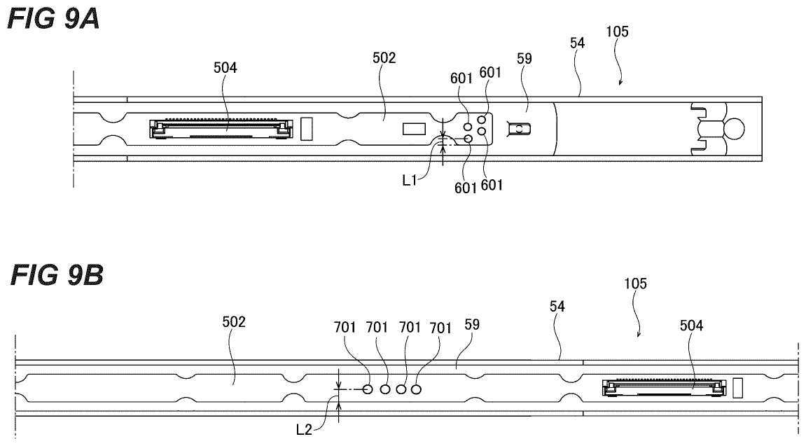

Here, the first check pad 601 after applying the sealant 59 is illustrated in FIG. 9A. A distance L1 illustrated in FIG. 9A is a distance in the short direction between the first check pad 601 and the sealant 59 after the sealant 59 is applied. Here, at least some of the plurality of first check pads 601 are arranged side by side in the short direction of the substrate 502. For this reason, the sealant 59 is applied to the four sides of the substrate 502, so that the sealant 59 approaches the first check pad 601, and the distance L1 may be reduced. Although the distance L1 is clearly illustrated in FIG. 9A, there is a possibility that, for example, one of the plurality of first check pads 601 is buried in the sealant 59 due to an application variation of the sealant 59, a component size variation, a position variation, and the like during manufacturing, and there is no distance L1. As a result, there is a possibility that the first check pad 601 becomes unusable after the sealant 59 is applied.

On the other hand, the second check pad 701 after applying the sealant 59 is illustrated in FIG. 9B. A distance L2 illustrated in FIG. 9B is a distance in the short direction between the second check pad 701 and the sealant 59 after the sealant 59 is applied. Here, the plurality of second check pads 701 is arranged side by side in the longitudinal direction of the substrate 502. That is, the plurality of second check pads 701 is arranged in a row in the longitudinal direction. As a result, a relationship between the distance L1 and the distance L2 satisfies L1<L2. The second check pad 701 has a larger distance from the sealant 59 than the first check pad 601, so that the LED chip 639 can emit light and be adjusted by the check pad even after the sealant 59 is applied.

As illustrated in FIG. 1D, when the second check pad 701 is provided at the center of the substrate 502, the pressing force F by a contact probe as a contact terminal connected to the above-described adjustment tool is also applied to the center of the substrate 502. However, after the substrate 502 and the lens array 506 are adhered and fixed, the rigidity of the substrate 502 and the entire optical print head 105 is high, and even if the pressing force F by the contact probe is applied to the center of the substrate 502, the influence of the partial deflection to the substrate 502 and the deflection to the entire optical print head 105 is slight. Therefore, the second check pad 701 can be disposed inside the first check pad 601. Furthermore, the second check pad 701 can be disposed at a position overlapping the region of the substrate 502 where the LED chip 639 is mounted.

According to the present embodiment, by including the plurality of check pads having the same function, it is possible to properly use check pads at optimal positions for each manufacturing process. Specifically, it is possible to use the first check pad 601 in an adjustment process before adhering with an adhesive, and to use the second check pad 701 in an inspection process after sealing with a sealant. As a result, even before adhering the substrate with the adhesive or after applying the sealant to the substrate, it is possible to perform adjustment and inspection using the contact (check pad) while minimizing the influence of deflection of the portion of the substrate on which the LED chip is mounted.

Note that, in the above-described embodiment, the positions and the number of the first check pads 601 and the second check pads 701 have been exemplified, without being limited thereto. In the present disclosure, a plurality of check pads having the same function may be provided.

In addition, in the above-described embodiment, the configuration in which the first check pads 601 are disposed at one end in the longitudinal direction of the substrate 502 has been exemplified, without being limited thereto. The first check pads 601 may be disposed at both ends in the longitudinal direction of the substrate.

In addition, in the above-described embodiment, the configuration in which two first check pads 601 are disposed in the short direction of the substrate 502 and one second check pad 701 is disposed in the short direction of the substrate 502 has been exemplified, without being limited thereto. At least one first check pad 601 may be disposed in the short direction of the substrate, and the configuration can be changed depending on the end region, the size of the substrate 502, and the distance to the sealant 59.

In addition, in the above-described embodiment, the configuration including the FFC connector 504 to which the cable is detachably connected has been exemplified, but without being limited thereto. For example, the first check pad 601 described above may be provided as an alternative to the connector 504. Also in this case, the first check pad 601 may be disposed at a position not overlapping the mounting region of the LED chip 639 of the substrate 502.

In addition, in the above-described embodiment, the configuration in which the first check pad 601 and the second check pad 701 are electrically connected to the light emitting element via the connector has been exemplified, without being limited thereto. The check pad may have another configuration as long as it is electrically connected to the light emitting element.

In addition, in the embodiment described above, the shapes of the first check pad 601 and the second check pad 701 are circular, without being limited thereto. The contact (check pad) only needs to be able to be in contact with the contact probe, and its shape may be, for example, a contact shape such as a rectangle or an ellipse in which a size in the short direction of the substrate 502 is larger than a size in the longitudinal direction of the substrate 502.

In addition, in the embodiment described above, the holder 54 is made of a metal, without being limited thereto. The holder 54 may be made of resin or another material.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims priority to and the benefit of Japanese Patent Application No. 2024-074766, filed May 2, 2024, the entirety of which is incorporated herein by reference.

What is claimed is:

1. An exposure device having an extended shape in an axial direction to expose a photoreceptor, the exposure device comprising:
a substrate including a plurality of light emitting elements configured to emit light for exposing the photoreceptor, the plurality of light emitting elements being arranged along the axial direction;
a lens array configured to condense light emitted from at least one light emitting element of the plurality of light emitting elements;
a holder configured to hold the substrate and the lens array;
a first contact electrically connected to the at least one light emitting element and configured to input a signal for controlling emission of light, wherein the first contact is contactable to and separable from the at least one light emitting element; and
a second contact positioned away from the first contact in a longitudinal direction of the substrate, the second contact electrically connected to the at least one light emitting element, and configured to input a signal for controlling emission of light, wherein the contact is contactable to and separable from the at least one light emitting element.

2. The exposure device according to claim 1, wherein
at least one of the first contact and the second contact does not overlap the light emitting element in the longitudinal direction.

3. The exposure device according to claim 1, wherein
the first contact includes a plurality of contacts arranged side by side in a direction orthogonal to the longitudinal direction.

4. The exposure device according to claim 1, wherein
the second contact includes a plurality of contacts, each arranged side by side in the longitudinal direction.

5. The exposure device according to claim 1, wherein
the second contact is larger in a direction orthogonal to the longitudinal direction than in the longitudinal direction.

6. The exposure device according to claim 1, wherein
the first contact is disposed at one end of the substrate in the longitudinal direction, and
the second contact is disposed within the first contact.

7. The exposure device according to claim 1, further comprising:
a connector electrically connected to the at least one light emitting element, wherein
a cable is detachably connected to the connector, and
the first contact is disposed closer to an end than the connector in the longitudinal direction.

8. The exposure device according to claim 1, wherein
the substrate has a plurality of wires configured to supply a signal to the at least one light emitting element, and
each of the first contact and the second contact includes a contact connected to a wire of the plurality of wires to supply the signal for controlling emission of light, and a contact connected to a wire of the plurality of wires to supply power to a respective light emitting element.

9. The exposure device according to claim 1, wherein
the first contact and the second contact are provided on a surface of the substrate opposite to a surface on which the at least one light emitting element is mounted.

10. The exposure device according to claim 1, wherein
the light emitting element is an organic electro-luminescence diode.

11. An image forming apparatus comprising:
a photoreceptor; and
the exposure device according to any claim 1.
